(19) United States
(12) Patent Application Publication
(10) Pub. No.: US 2012/0285505 A9
(43) Pub. Date: Nov. 15, 2012

(54) TRANSDUCER AND METHOD USING PHOTOVOLTAIC CELLS

(76) Inventors: Richard W. McCoy, JR., Lee Vining, CA (US); Richard W. McCoy, III, June Lake, CA (US)

(21) Appl. No.: 12/912,552

(22) Filed: Oct. 26, 2010

(51) Int. Cl. H01L 31/052; H01L 31/18; H01L 31/042

(52) U.S. Cl. 136/246; 136/251; 29/890.033

(57) ABSTRACT

Photovoltaic cells may be distributed upon an inner surface of a perimeter of a tubular structure. The tubular structure may be installed in the roof of a habitable or uninhabitable structure to provide low-profile solar energy.

### BACKGROUND

1. Field

This disclosure is generally related to photovoltaic cells and more particularly installations of photovoltaic cells.

2. Description of the Related Art

Increasing energy costs and the demand for dwindling natural resources are creating demand for renewable energy sources. Solar power, for example, offers an environmentally friendly, renewable, and reliable source of energy. In some parts of the world, solar power enables people to “live off the grid,” relying predominantly on solar power for their day to day energy needs.

One approach to harnessing solar power employs photovoltaic cells. It typically requires many hundreds or thousands of individual photovoltaic cells to produce appreciable amounts of electric power. The photovoltaic cells are typically arrayed in groups or arrays. The groups or arrays are typically formed as discrete panels (i.e., solar panels). the panels are generally rigid planar structures that have large surface areas to maximize the amount of solar insulation received. A typical home or residence may require several panels to produce sufficient levels of power to meet daily needs. Solar panels are often mounted to the roof of a structure. The structure may be habitable or not. Solar panels may also be supported on a pole or frame positioned on the ground. In any case, the generally flat configuration of many solar panels tends to consume vast amounts of real estate resources while blemishing the landscape with a large and conformingly unattractive presence.

The present disclosure provides an alternative to the present dilemma.

### BRIEF SUMMARY

A transducer may be summarized as including a tubular structure having a first end, a second end, a length extending between the first and the second ends, and a perimeter wall that forms a closed surface over a least a portion of the length of the tubular structure and which separates an interior of the tubular structure from an exterior thereof at least along the portion of the length; a light transmissive cover positioned to at least partially cover the first end of the tubular structure to preventingress of precipitation into the interior of the tubular structure while transmitting at least some wavelengths of light therein; and a plurality of photovoltaic cells disposed within the interior of the tubular structure along at least the portion of the length of the tubular structure and oriented to receive at least a portion of the light transmitted via the light transmissive cover.

The transducer may further include a light transmissive member positioned at least proximate the second end of the tubular structure to at least partially pass the light transmitted via the light transmissive cover out from the interior of the tubular structure. The transducer may instead further include a reflective member that is at least partially reflective of the at least some wavelengths of light, the reflective member positioned at least proximate the second end of the tubular structure to at least partially reflect the light transmitted via the light transmissive cover back towards the photovoltaic cells. The light transmissive cover of the transducer may be convex in a direction that points outward from the first end of the tubular structure. The light transmissive cover of the transducer may be a diffusive lens that scatters the light that the light transmissive cover transmits into the interior of the tubular structure. The tubular structure of the transducer may have at least a portion of the tubular structure have a polygonal cross-section having a number of flat sections. Additionally, the photovoltaic cells the transducer may be carried by the flat sections of an inner surface of the tubular structure. At least a portion of the tubular structure of the transducer may have a hexagonal cross-section and a straight longitudinal axis. The light transmissive cover of the transducer may be coupleable to the tubular structure, and further comprise a flange that extends beyond the perimeter wall of the tubular structure when the light transmissive cover is coupled to the tubular structure. The transducer may further include an exhaust port adaptable to a ventilation device, the ventilation device to remove moisture from the tubular structure. Additionally, the ventilation device may be a passive fan.

An energy conversion system installed in a structure having a roof and an interior may include a tubular structure having a first end, a second end, a length extending between the first and the second ends, and a perimeter wall, at least the first end of the tubular structure extending from a portion of the roof of the structure; a light transmissive cover positioned to at least partially cover the first end of the tubular structure to preventingress of precipitation into the interior of the structure while transmitting at least some wavelengths of light therethrough; and a plurality of photovoltaic cells coupled to the tubular structure and oriented to receive at least a portion of the light transmitted via the light transmissive cover. The perimeter wall of the tubular structure of the energy conversion system may form a closed surface over a least a portion of the length of the tubular structure which separates an interior of the tubular structure from an exterior thereof. The structure of the energy conversion system may be a habitable structure. Additionally, the first end of the tubular structure may extend vertically from the portion of the roof. The habitable structure of the energy conversion system may include at least one room and the second end of the tubular structure is coupled to provide light into the room of the habitable structure. The energy conversion system may further include a light transmissive member positioned at least proximate the second end of the tubular structure to at least partially pass the light transmitted via the light transmissive cover out from the interior of the tubular structure into the room of the habitable structure. At least a portion of the tubular structure of the energy conversion system may have a polygonal cross-section having a number of flat sections and the photovoltaic cells are carried by the flat sections of an inner surface of the tubular structure. The tubular structure of the energy conversion system may include at least two distinct segments that have been joined together. The energy conversion system may further include at least one flange that extends beyond the perimeter wall of the tubular structure when the light transmissive cover is coupled to the tubular structure; and at least one piece of flashing positioned between at least the portion of the length of the tubular structure and the portion of the roof of the structure.

A method of installing photovoltaic cell system in a structure having a roof may include providing a tubular structure having a first end, a second end, a passage extending between the first and the second ends, a length extending between the first end and the second end, and a plurality of photovoltaic cells distributed in the passage of the tubular structure; mounting the tubular structure to the structure such that at least a portion of the first end of the tubular structure extends out of the structure and at least a portion of the second end of the tubular structure extends to an interior of the structure; and positioning a light transmissive cover proximate to the first end of the tubular structure to at least partially cover the first end. The method may further include installing flashing between the tubular structure and the roof of the structure, wherein the structure is a habitable structure. The method may further include positioning the second end of the tubular structure to transmit sunlight from the interior of the tubular structure to a room in the habitable structure.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are enlarged and positioned to improve drawing legibility. Further, the particular shapes of the elements as drawn, are not intended to convey exact information regarding the actual shape of the particular elements, and have been selected for ease of recognition in the drawings.

FIG. 1 is an isometric view of an energy conversion system, including tubular structures according to one illustrated embodiment, the tubular structures installed in the roof of a habitable structure.

FIG. 2 is a side cutaway view of a tubular structure installed in a roof and which transmits light into a habitable structure, according to one illustrated embodiment.

FIG. 3 is a top cutaway view of the tubular structure illustrated in FIG. 2, according to one illustrated embodiment.

FIG. 4 is a side cutaway view of a tubular structure installed in a roof and which reflects light from the bottom of the habitable structure, according to one illustrated embodiment.

FIG. 5 is a top cutaway view of the tubular structure illustrated in FIG. 4, according to one illustrated embodiment

FIG. 6 is a side cutaway view of a tubular structure installed in a roof and which transmits light into a habitable structure, according to one illustrated embodiment.

FIG. 7 is a top cutaway view of the tubular structure illustrated in FIG. 6, according to one illustrated embodiment.

FIG. 8 is an isometric view of a portable energy conversion system, including several tubular structures, according to one illustrated embodiment.

FIG. 9 is a top plan view of the portable energy conversion system of FIG. 8, according to one illustrated embodiment.

FIG. 10 is an isometric view of a tubular structure that could be incorporated into the energy systems illustrated in FIGS. 1-10, according to one illustrated embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known structures associated with the energy conversion systems such as electrical power converters, switches, relays, circuit breakers, etc., have not been shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

The headings and Abstract of the Disclosure provided herein are for convenience only and do not interpret the scope or meaning of the embodiments.

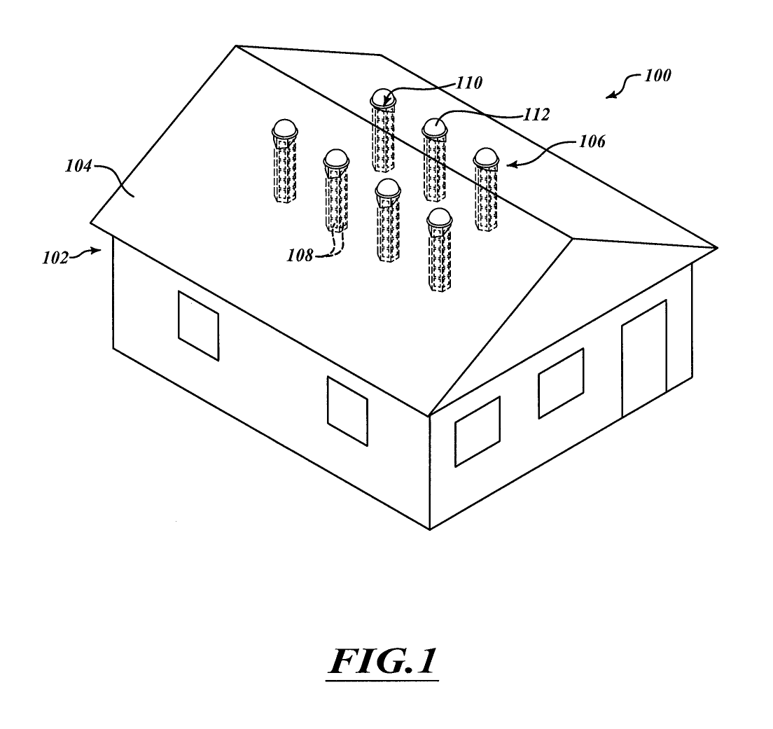

FIG. 1 illustrates an energy conversion system 100 installed in a habitable structure 102 having a roof 104, according to one illustrated embodiment.

The energy conversion system 100 includes tubular structures 106 carrying transducers, such as photovoltaic cells 108, and covers 112.

The tubular structures 106 are through the roof 104 of the habitable structure 102. The tubular structures 106 include a portion extending above the roof 104 and a portion extending below the roof 104. The portion of the tubular structures 106 extending above the roof 104 are positioned to receive electromagnetic radiation, e.g., sunlight, through at least one end. The received electromagnetic radiation is directed to an interior 110 of the tubular structures 106 so as to expose portions or exposed faces of the photovoltaic cells 108 to the electromagnetic radiation. The tubular structures 106 are illustrated as being through the roof 104; however, in other embodiments, the tubular structures 106 are installed around, above, or in proximity to the roof 104 or other surfaces of the habitable structure 102. In one embodiment, the habitable structure 102 is a residential building, such as a house, an apartment building, a duplex, or a townhouse. In another embodiment, the habitable structure 102 is a non-residential building, such as a store, a doctor's office, a warehouse, or a commercial office space.

The tubular structures 106 may have any of a variety of cross-sectional shapes or profiles. In one embodiment, the tubular structures 106 have a hexagonal cross-sectional shape. In another embodiment, the tubular structures 106 are generally cylindrical, having a circular cross-sectional shape. In another embodiment, the tubular structures 106 have a polygonal cross-sectional shape and include any number of flat surfaces coupled together to form a fully enclosed or an at least partially enclosed perimeter, e.g., triangular, pentagonal, octagonal, decagonal, or the like. Other embodiments of the tubular structures 106 include any combination of the cross-sectional shapes discussed above. For example, the portion of the tubular structures 106 extending through and above the roof 104 have a cylindrical cross-sectional shape while some of the portion of the structure below the roof 104 could have a polygonal cross-sectional shape.

The tubular structures 106 may be formed by multiple segments. Thus, the tubular structures 106 could be manufactured as smaller pieces to be assembled into larger structures before or during installation. One or more of the segments may not be straight, i.e., curved, angled, tapered in, or tapered out, such that an end of the tubular structure 106 is tapered in or is flared out. A non-straight segment or segments of the structure could be used to increase the quality or quantity of electromagnetic radiation received into an interior of the tubular structure 106 or by transducers carried thereby.

The tubular structures 106 may be manufactured from any of a large variety of materials. For example, the tubular structures 106 may be manufactured with a weather resistant metal, such as galvanized steel. The tubular structures 106 may be manufactured from another pliable metal, such as aluminum. Alternatively, or additionally, the tubular structures 106 may be manufactured from a plastic or a composite that is not electrically conductive. For example, the tubular structures 106 may be manufactured from a metal or metal alloy and at least partially coated on an interior surface with a nonconductive coating. This coating facilitates electrical isolation of the photovoltaic cells 108 and any other electrical devices or paths carried by the tubular structures 106. The tubular structures may be manufactured or assembled using a combination of materials, such as steel, plastic, or/and a composite. For example, the tubular structures 106 may be manufactured from metal or metal alloy with a weather resistant plastic, polymer, or resin coating on an exterior surface thereof.

In one embodiment the transducers carried by the tubular structures 106 are photovoltaic cells 108. The photovoltaic cells 108 are dispersed about an interior surface of the tubular structure 106. The photovoltaic cells 108 may be directly adhered to the tubular structure 106. The tubular structures 106 are positioned so as to receive light from the sun and direct the light onto the exposed surfaces or faces of the photovoltaic cells 108. The photovoltaic cells 108 may take the form of other transducers, such as solar cells, heat transducers, or the like. Photovoltaic cells 108 may be manufactured to be sensitive to a particular range of wavelengths within the electromagnetic spectrum. All of the photovoltaic cells 108 may be manufactured to be sensitive to the same range of wavelengths within the electromagnetic spectrum. Alternatively, some of the photovoltaic cells 108 may be manufactured to be sensitive to a first range of wavelengths within the electromagnetic spectrum, and others of the photovoltaic cells 108 are manufactured to be sensitive to a second range of wavelengths within the electromagnetic spectrum. Some of the tubular structures 106 may carry photovoltaic cells 108 that are sensitive to a first range of wavelengths, while other ones of the tubular structures 106 carry photovoltaic cells 108 that are sensitive to a second range of wavelengths.

The cover 112 illustrated in FIG. 1 is a light transmissive (i.e., transparent or partially transmissive) cover. Cover 112 may be made of a plastic or acrylic that is durable, resistant to inclement weather, resistant to the effects of long-term UV exposure, and inexpensive. As shown, the cover 112 is outwardly convex; this shape assisting in guiding precipitation away from the tubular structure 106. In one embodiment, the cover 112 is constructed of glass. In another embodiment the tubular cover 112 is manufactured to filter and only transmit and disperse light of a particular range of wavelengths into the interior of the tubular structure 106.

The cover 112 can take any of a large variety of different shapes and sizes. For example, the cover 112 may be pyramidal with three, four, or more flat surfaces. Also for example, the cover may be hemispherical or dome-shaped. These configurations also guide precipitation away from the interior of the tubular structure 106 while allowing the passage of light. As a further example, the cover 112 may be a single flat surface, for instance relying on a non-vertical orientation of the tubular structure 106 or an end of the tubular structure 106 to guide precipitation from the surface of the cover 112.

The tubular cover 112 may be formed as a lens that redirects light transmitted by the cover 112 toward a specific region or regions on the interior 110 of the tubular structure 106. The lens can be constructed to converge or focus beams of light. For example, the cover 112 may focus light towards a dispersive element carried in or by the interior 110 of the tubular structure 106. Alternatively, the cover 112 may dispense or refractively diverge the beams of light.

As explained above, the tubular cover 112 may be formed as a lens. The tubular cover 112 may be moveably mounted to the tubular structure 106. The tubular cover 112 is then rotated or otherwise positioned to direct a principal axis of the lens toward the Sun. The tubular structure 106 may contain additional reflective and/or refractive elements or coatings. The tubular structure 106 may also house or carry mechanisms actuators (e.g., electric motors, solenoids, hydraulic pumps) and/or drive mechanisms (e.g., gears, linkages) to make possible the manual or automated rotation or redirection of the tubular cover 112.

The tubular structures 106 have a relatively higher density of photovoltaic cells 108 per unit of exposed surface area of the habitable structure occupied by the tubular structure, in comparison to an essentially flat configuration of a solar panel or solar cell array. One benefit of such is that more transducers can be utilized and positioned within a defined area, such as a roof. In locations where energy costs demand either a decrease in consumption or subsidy of energy resources, the configuration of the energy conversion system illustrated in FIG. 1 functions to alleviate some of the potential real estate issues related to spreading large numbers of essentially flat solar panels over the area of a roof, other surfaces of a habitable structure, or on the surrounding terrain.

The number or orientation of tubular structures 106 illustrated in FIG. 1 should not be interpreted as a limitation on this disclosure. More or less tubular structures 106 may be positioned extending through the roof 104. The tubular structures 106 may all be positioned on one side of a ridge of the roof 104 or the other. For example, in the Northern Hemisphere, the tubular structures 106 may be arranged on a south facing side of the roof 104. The tubular structures 106 may be angled or oriented non-vertically in any number of directions, according to an embodiment. Alternately, a protruding end of a distal portion of the tubular structures 106 may be angled or beveled.

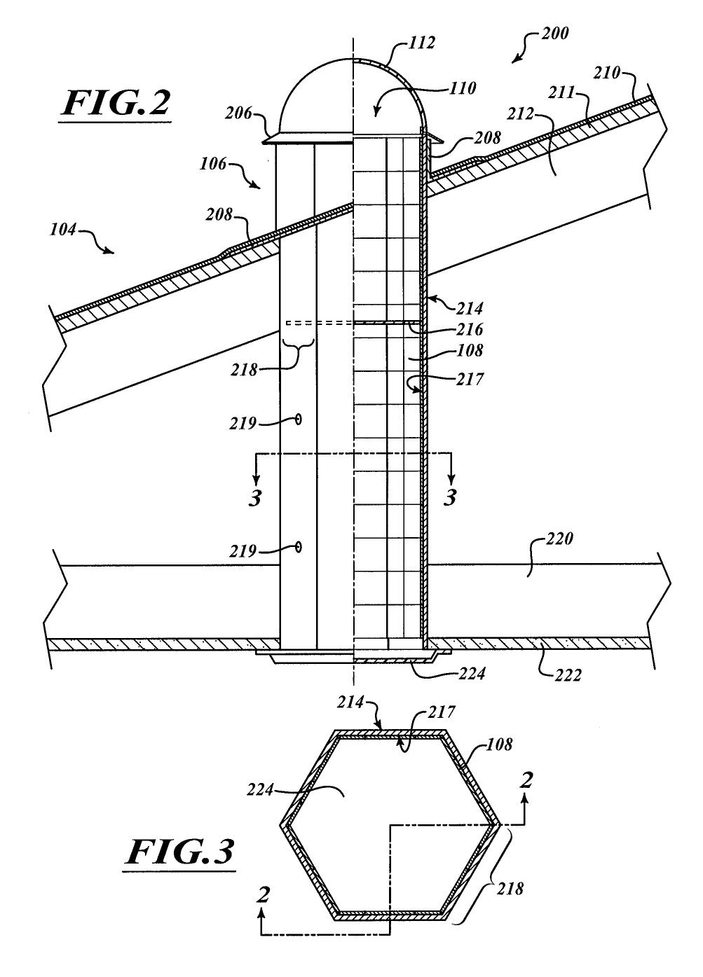

FIGS. 2 and 3 show the tubular structure 106 of FIG. 1 extending through the roof 104 and a ceiling 222 of habitable structure 102, according to one illustrated embodiment. Transducer 200 includes rain drip flange 206, flashing 208, roofing material 210, sheathing 211, and roof rafter 212. Transducer 200 also shows exterior surface 214, light diffuser 216, photovoltaic cells 108, ceiling joist 220, ceiling 222 and tubular cover 224.

FIG. 2 illustrates materials useful for weather protecting the tubular structure 106 and the habitable structure 102. Rain drip flange 206 redirects precipitation flowing from cover 112 away from the tubular structure 106. The rain drip flange 206 may be rotatably mounted onto the tubular structure 106 to enable the tubular cover 112 to direct the principal axis of a lens toward the Sun.

Flashing 208 abuts an exterior surface 214 of the tubular structure 106 and is positioned between roofing material 210 and sheathing 211 to provide a moisture barrier and to protect the materials lying beneath. The flashing 208 can be made of thin metal that closely surrounds the outer perimeter of the exterior surface 214. The flashing 208 can be angled away from the exterior surface 214 toward the roofing material 210 to create another mechanism by which precipitation is directed away from a junction of the tubular structure 106 with the roof 104. The roofing material 210 is made of asphalt or wood shingles. Alternatively, the roofing material 210 is made from tile, torched down material, or the like.

FIG. 2 also illustrates materials used to interface the tubular structure 106 with the habitable area of the habitable structure 102. One or more ceiling joists 220 support one end of the tubular structure 106. The ceiling 222 is affixed to the ceiling joist 220, and is typically made of sheet rock, ceiling tile, wood, or a suitable ceiling material. The cover 224 is positioned to cover an end of the tubular structure 106 that is distal to the roof. In one embodiment the cover 224 is light transmissive (e.g., transparent or partially transmissive) and disperses light into the habitable area, such as a room. The cover 224 may diffuse the light. Alternatively, the cover 224 may be constructed from a semi-reflective material (e.g., dichromatic), transmitting only a portion of the light incident from the tubular structure 106 while reflecting a portion of the light back up the tubular structure 106. Positioning the cover 224 in this manner, with respect to tubular structure 106, enables the tubular structure 106, the cover 112, and the cover 224 to function as a skylight for the habitable structure 102.

The optional light diffuser 216 receives incident light from the cover 112 and disperses the light toward the photovoltaic cells 108. The light diffuser 216 may be positioned proximal to the cover 112, near the middle of a length of the tubular structure 106 (as shown), or it may be positioned anywhere along the length of the tubular structure 106. The light diffuser 216 may be constructed from plastic, glass, or a composite effective for dispersing incident light towards the interior surface of the tubular structure 106.

FIGS. 2 and 3 also show the photovoltaic cells 108 carried by the tubular structure 106. The photovoltaic cells 108 receive electromagnetic radiation passed by the cover 112 into the interior of the tubular structure 106. The photovoltaic cells 108 may be adhered directly to an interior surface 217 of the tubular structure 106. The interior surface 217 of the tubular structure 106 may be coated with a nonconductive coating, and the photovoltaic cells 108 adhered to the nonconductive surface formed by the coating. The arrays of photovoltaic cells 108 may be flexible, so as to be conveniently carried by or adhered to a curved interior surface of a cylindrical tubular structure 106. More typically, arrays of the photovoltaic cells 108 are rigid, and are carried by a least some of the flat surfaces 218 (i.e., flats) of the interior surface 217 of the polygonal tubular structure 106. The photovoltaic cells 108 may extend along the entire length of the interior surface 217 of the tubular structure 106. Alternatively, the photovoltaic cells 108 may be carried along less than the full length of the interior surface 217 of the tubular structure 106.

The photovoltaic cells 108 receive light passed or transmitted by cover 112. The photovoltaic cells 108 are devices that directly convert electromagnetic radiation into electricity (i.e., electrical current). The photovoltaic cells 108 can be manufactured to convert a narrow, medium, or wide range of energy or wavelengths from the electromagnetic spectrum into electricity. The photovoltaic cells 108 may be designed to convert a substantially similar range of radiation from the electromagnetic spectrum into electricity. Alternatively, sets of the photovoltaic cells 108 may be designed to respectively convert two or more ranges of energy from the electromagnetic spectrum into electricity. The resulting electric current is routed to supply the energy demands of the habitable structure 102 and any occupants thereof. The electricity may be diverted to various power converters (e.g., DC/DC, DC/AC) and/or energy storage devices, such as one or more batteries, or ultracapacitors. The electricity may be used to power machinery which is configured to mechanically store energy, such as pumping water into a water tower. The photovoltaic cells 108 may be designed to convert a narrow range of energy from the electromagnetic spectrum. The cover 112 may be constructed to filter out undesirable wavelengths of the electromagnetic spectrum. The light diffuser 216 may alternatively or additionally be constructed to filter out undesired wavelengths of the incident electromagnetic spectrum. Some of the transducers may convert heat into electricity.

The tubular structure 106 may include one or more exhaust ports 219 providing a fluid passage between an interior and an exterior of the tubular structure 106. The exhaust port 219 may cooperate with a passive or active ventilation device. The ventilation device helps to remove moisture and/or heat from the interior of the tubular structure 106. The exhaust port 219 may take the form of small apertures, large apertures, round, curved, or polygonal shaped apertures. The ventilation device may take the form of an active mechanism, such as a pump, fan, or synthetic jet air mover. The ventilation device is constructed from a diaphragm or may rely on the Bernoulli or “chimney” effect. The ventilation device may circulate air in the interior of the tubular structure 106. Optionally, desiccant, such as calcium sulfate or calcium chloride may be employed to regulate moisture levels in the interior of the structure.

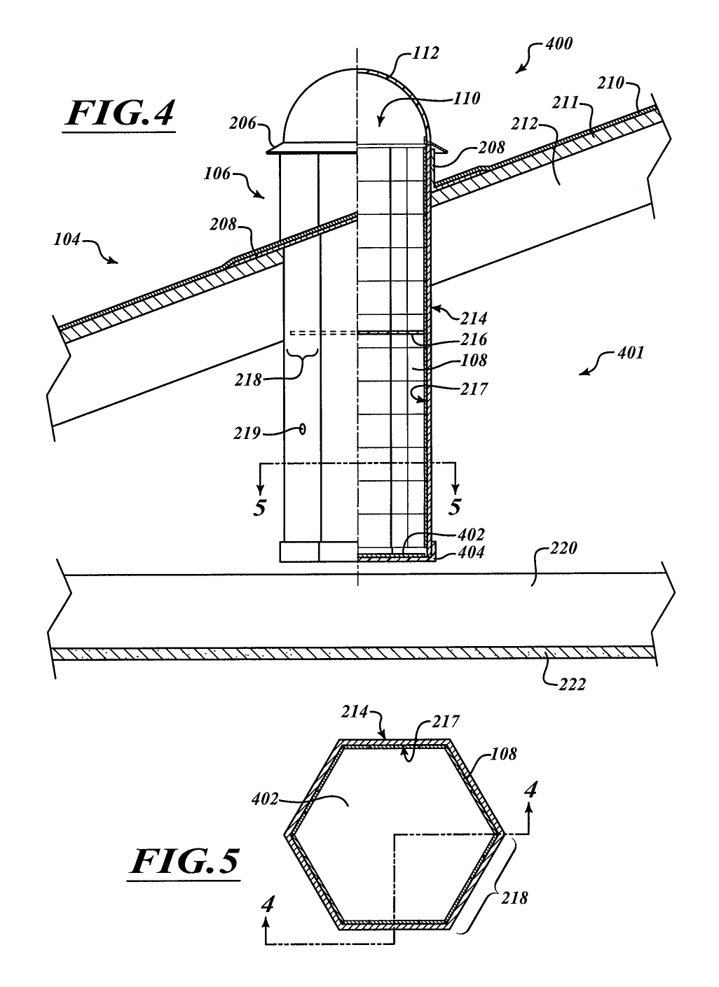

FIGS. 4 and 5 show a transducer 400 including the tubular structure 106 installed in the roof 104 of habitable structure 102, according to one illustrated embodiment.

The embodiment of FIGS. 4 and 5 is similar in many respects to that of FIGS. 3 and 4. Thus, similar elements are denoted by the same reference numerals. Only significant differences are discussed below, in the interest of brevity and hence clarity.

The tubular structure 106 of the transducer 400 terminates in a space 401 between roofing material 210 and ceiling 222. A reflective member 402 is positioned proximate an end of the tubular structure 106 that is distal to the roof 104. The reflective member 402 reflects incident light back onto the surfaces of photovoltaic cells 108. The reflective member 402 advantageously redirects energy that was not initially absorbed by the photovoltaic cells 108 as well as energy that may not have been initially directed onto an exposed face of a photovoltaic cell 108.

The cover 404 is positioned over an end of the tubular structure 106 that is distal to the roof 104, according to one embodiment. The cover 404 covers an end of the tubular structure 106 and may extend over a portion of an exterior surface 214 perimeter of the tubular structure 106. Alternatively, the cover 404 may terminate co-terminally on a portion of an interior surface 217 of the tubular structure 106. The reflective characteristics of the reflective member 402 may be incorporated into cover 404 so that the cover 404 reflects incident light onto the surfaces of the photovoltaic cells 108 without a reflection member 402. The tubular structure 106 may be terminated by the cover 404 above the ceiling joist 220. Alternatively, the tubular structure 106 extends to a location equal to or lower than the top of ceiling joist 220. As shown in FIG. 4, the tubular structure 106 of transducer 400 may not extend through the ceiling 222.

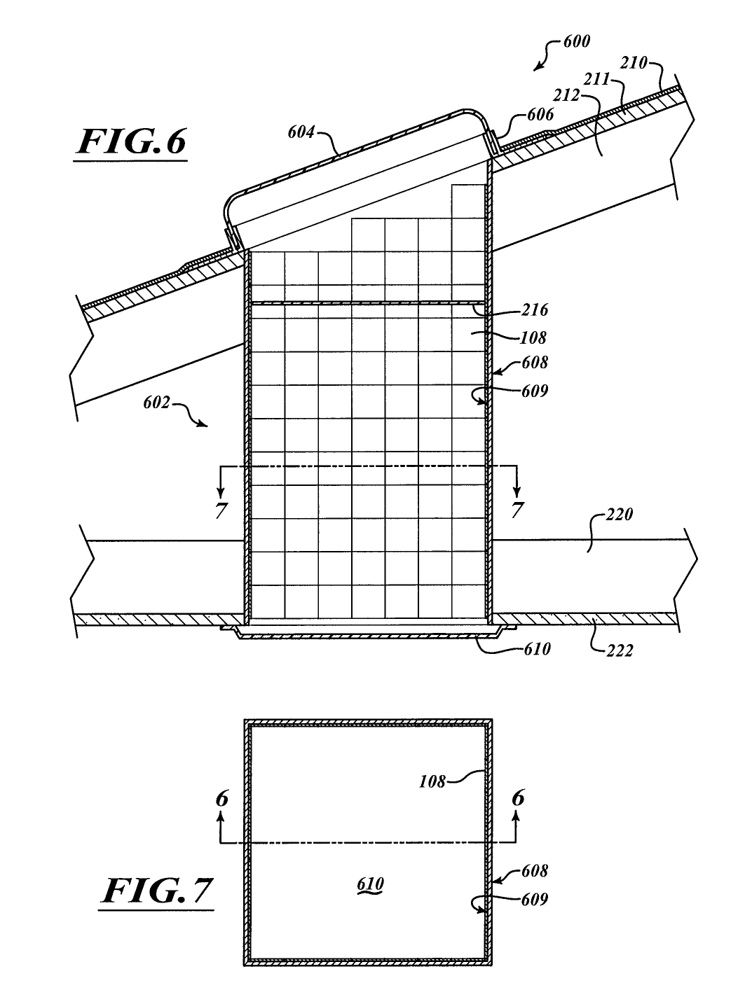

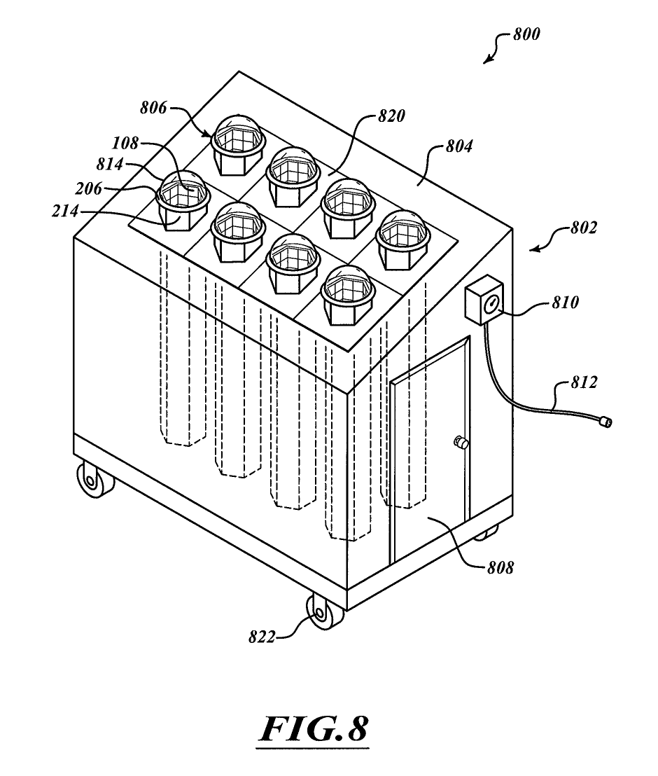

FIGS. 6 and 7 show a transducer 600 including a tubular structure 602 as installed in the roof 104 of habitable structure 102, according to one illustrated embodiment.

The embodiment of FIGS. 6 and 7 are similar in some respects to that of other previously described embodiments. Identical or similar structures are identified by the same reference numbers as used in previous embodiments. Only significant differences in structures and operation will be discussed.

The transducer 600 includes a tubular structure 602 and cover 604.

The tubular structure 602, the cover 604, and/or the cover 610 may be commercially available components for a skylight. The tubular structure 602, the cover 604, and/or the cover 610 may be rectangular or square in cross-section or profile. The tubular structure 608 may, for example, be manufactured from galvanized steel and be resistant to inclement weather and precipitation. Alternatively, the tubular structure 602 may be manufactured from other metals, plastic, polymer, resin composite, or any combination thereof. The cover 604 may be manufactured from a UV protected plastic. The cover 604 may form or include a filter which selectively transmits particular ranges of the electromagnetic radiation spectrum. The cover 604 may form or include a lens to direct electromagnetic energy (e.g., light) onto the exposed surfaces of the photovoltaic cells 108. An optional light diffuser 216 may be positioned within the interior of the tubular structure 602. The cover 610 may be plastic or glass. The cover 610 may be transparent or partially reflective, or be constructed to filter out particular ranges of the electromagnetic spectrum. The cover 610 is positioned to provide light into a room in which the cover 610 is mounted.

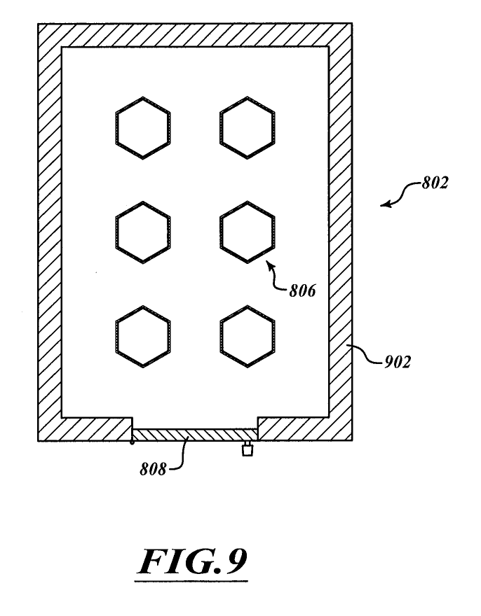

FIGS. 8 and 9 show an energy conversion system 800, according to one illustrated embodiment.

The energy conversion system 800 is installed in a portable structure 802 having a roof 804, an access panel 808, a meter 810, and an electrical coupler 812. The energy conversion system includes a number of tubular structures 806 extending through the roof 804.

The portable structure 802 conveniently provides portable energy without requiring the installation of a fixture on a property, according to one embodiment. The portable structure may not be habitable, having sufficiently small dimensions and/or lack of unoccupied interior space. The portable structure 802 may be constructed of metal and may be of any desired shape. An outer wall 902 of the portable structure 802 may be constructed of a thick material, such as steel, to keep the tubular structures 806 securely enclosed. In one embodiment, the outer wall 902 is insulated to increase the efficiency of and maintain an operating temperature of the photovoltaic cells 108 enclosed within tubular structures 806. The portable structure 802 optionally includes wheels 822 which allow relatively easy repositioning. Alternatively, the portable structure 802 may have bottom brackets to facilitate repositioning with a forklift, or the like. The access panel 808 may be a flat or curved section of wood or metal, such as a door. The portable structure 802 may have a rectangular, polygonal, curved, or round perimeter. The portable structure 802 may be hemispherical.

The tubular structures 806 extend through the roof 804 of the portable structure 802. Additionally or alternatively, tubular structures 806 may be installed extending through a wall 902 of the portable structure 802. A cover 814 is positioned over each tubular structure 806. Structures of the embodiment of FIG. 8 which are similar or identical to structures of previously described embodiments are identified by the same reference numbers, and discussion of these structures will not be repeated. Only significant differences are discussed below.

The length of the tubular structure 806 is illustrated as extending below the roof 804 of the portable structure 802. However, the tubular structure 806 may be shorter or longer than depicted.

The illustrated portable energy conversion system 800 depicts eight tubular structures 806. This illustration is exemplary, and is not intended to be limiting. The portable structure 802 may have more or less tubular structures 806, in accordance with the spirit of this disclosure.

The tubular structure 806 may be installed using modular paneling 820. The modular paneling 820 can be coupled to other modular panels using snap mechanisms, screws, nuts and bolts, expandable plugs, or the like, according to embodiments of the disclosure. The modular paneling 820 enables installation and removal of tubular structures 806 with relative ease for professional and non-professional installers alike.

The meter 810 and electrical coupler 812 provide a user interface to be captured energy. The meter 810 includes a voltmeter, an ammeter, supplied maximum power reading, average output power reading, and a clock or timing mechanism, according to one embodiment. The meter 810 may also include a transceiver that can be interfaced with a network, such as Wi-Fi, to provide remote access to information supplied by the meter. The portable structure 802 may house power conversion equipment such as transformers, rectifiers, DC/DC converters, and/or AC/DC converters. The portable structure 802 may additionally or alternatively house energy storage devices such as batteries and/or ultracapacitors.

The energy conversion system 800 may have many applications. Such may advantageously enable tenants to benefit from alternative energy sources without having to install fixtures on a landlord's property. The energy conversion system may be positioned in a location proximate an apartment complex, extended-stay motel, the yard of a townhouse, outside an office building, a store, or a house. Larger and smaller units may be constructed according to the energy needs of the user.

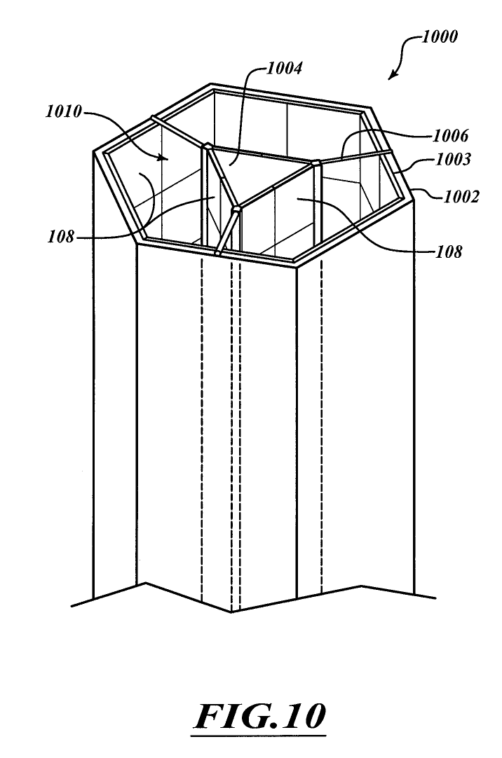

FIG. 10 shows a tubular structure 1000 and photovoltaic cells 1008 that could be incorporated into the energy system of FIGS. 1-9.

An inner frame 1004 is received in an interior 1010 of the tubular structure 1000. Spacers 1006 may physically couple the inner frame 1004 to the tubular structure 1000. The tubular structure 1000 may be hexagonal, cylindrical, or polygonal (i.e., comprising several flat surfaces joined together to form an enclosed tubular perimeter).

The inner frame 1004 is positioned away from an inner surface 1003 of the tubular structure 1000. The inner frame 1004 may, for example, have a triangular cross-section and/or may form a truss work. The inner frame 1004 may be approximately the same length as tubular structure 1000. Alternatively, the inner frame 1004 may have a cylindrical or polygonal cross-section and may be longer or shorter than the length of the tubular structure 1000. The inner frame 1004 may be tapered outwardly or inwardly so as to flare or taper at least part of the length along the inner frame 1004.

The spacers 1006 position the inner frame 1004 away from an inner surface of the tubular structure 1000. The spacers 1006 may be fixably or movably mounted to the tubular structure 1000. The spacers 1006 may be metallic and attached to at least two locations on the inner frame 1004 and at least two locations on the tubular structure 1000. The spacers 1006 may be constructed of a wire, cable, cord, line, string, or a similar flexible material. Alternatively, the spacers 1006 may take the form of a rod, a beam, or a bracket. The spacers 1006 may be attached proximate one end of the tubular structure 1000. Alternatively, the spacers 1006 may be attached proximate to more than one end of the tubular structure 1006. Alternatively, or additionally, the spacers 1006 are affixed to the tubular structure 1000 somewhere between the ends of the tubular structure 1000.

The foregoing detailed description has set forth various embodiments of the devices and/or processes via the use of diagrams and examples. Insofar as such diagrams and examples contain one or more functions and/or operations, it will be understood by those skilled in the art that each function and/or operation within such diagrams or examples can be implemented, individually and/or collectively, by a wide range of hardware, software, firmware, or virtually any combination thereof.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transducer, comprising:
a tubular structure having a first end, a second end, a length extending between the first and the second ends, and a perimeter wall that forms a closed surface over a least a portion of the length of the tubular structure and which separates an interior of the tubular structure from an exterior thereof at least along the portion of the length;
a light transmissive cover positioned to at least partially cover the first end of the tubular structure to prevent ingress of precipitation into the interior of the tubular structure while transmitting at least some wavelengths of light therein; and
a plurality of photovoltaic cells disposed within the interior of the tubular structure along at least the portion of the length of the tubular structure and oriented to receive at least a portion of the light transmitted via the light transmissive cover.

2. The transducer of claim 1, further comprising:
a light transmissive member positioned at least proximate the second end of the tubular structure to at least partially pass the light transmitted via the light transmissive cover out from the interior of the tubular structure.

3. The transducer of claim 1, further comprising:
a reflective member that is at least partially reflective of the at least some wavelengths of light, the reflective member positioned at least proximate the second end of the tubular structure to at least partially reflect the light transmitted via the light transmissive cover back towards the photovoltaic cells.

4. The transducer of claim 1 wherein the cover is convex in a direction that points outward from the first end of the tubular structure.

5. The transducer of claim 1 wherein the light transmissive cover is a diffusive lens that scatters the light that the light transmissive cover transmits into the interior of the tubular structure.

6. The transducer of claim 1 wherein at least a portion of the tubular structure has a polygonal cross-section having a number of flat sections.

7. The transducer of claim 6 wherein the photovoltaic cells are carried by the flat sections of an inner surface of the tubular structure.

8. The transducer of claim 1 wherein at least a portion of the tubular structure has a hexagonal cross-section and a straight longitudinal axis.

9. The transducer of claim 1 wherein the light transmissive cover is coupleable to the tubular structure, and further comprising:
a flange that extends beyond the perimeter wall of the tubular structure when the light transmissive cover is coupled to the tubular structure.

10. The transducer of claim 1, further comprising:
an exhaust port adaptable to a ventilation device, the ventilation device to remove moisture from the tubular structure.

11. The transducer of claim 10 wherein the ventilation device is a passive fan.

12. An energy conversion system installed in a structure having a roof and an interior, the energy conversion comprising:
a tubular structure having a first end, a second end, a length extending between the first and the second ends, and a perimeter wall, at least the first end of the tubular structure extending from a portion of the roof of the structure;
a light transmissive cover positioned to at least partially cover the first end of the tubular structure to prevent ingress of precipitation into the interior of the structure while transmitting at least some wavelengths of light therethrough; and
a plurality of photovoltaic cells coupled to the tubular structure and oriented to receive at least a portion of the light transmitted via the light transmissive cover.

13. The energy conversion system of claim 12 wherein the perimeter wall of the tubular structure forms a closed surface over a least a portion of the length of the tubular structure which separates an interior of the tubular structure from an exterior thereof.

14. The energy conversion system of claim 12 wherein the structure is a habitable structure.

15. The energy conversion system of claim 14 wherein the first end of the tubular structure extends vertically from the portion of the roof.

16. The energy conversion system of claim 14 wherein the habitable structure includes at least one room and the second end of the tubular structure is coupled to provide light into the room of the habitable structure.

17. The energy conversion system of claim 16, further comprising:
a light transmissive member positioned at least proximate the second end of the tubular structure to at least partially pass the light transmitted via the light transmissive cover out from the interior of the tubular structure into the room of the habitable structure.

18. The energy conversion system of claim 13 wherein at least a portion of the tubular structure has a polygonal cross-section having a number of flat sections and the photovoltaic cells are carried by the flat sections of an inner surface of the tubular structure.

19. The energy conversion system of claim 13 wherein the tubular structure includes at least two distinct segments that have been joined together.

20. The energy conversion system of claim 13, further comprising:
at least one flange that extends beyond the perimeter wall of the tubular structure when the light transmissive cover is coupled to the tubular structure; and
at least one piece of flashing positioned between at least the portion of the length of the tubular structure and the portion of the roof of the structure.

21. A method of installing photovoltaic cell system in a structure having a roof, the method comprising:
providing a tubular structure having a first end, a second end, a passage extending between the first and the second ends, a length extending between the first end and the second end, and a plurality of photovoltaic cells distributed in the passage of the tubular structure;
mounting the tubular structure to the structure such that at least a portion of the first end of the tubular structure extends out of the structure and at least a portion of the second end of the tubular structure extends to an interior of the structure; and
positioning a light transmissive cover proximate to the first end of the tubular structure to at least partially cover the first end.

22. The method of claim 21, further comprising:
installing flashing between the tubular structure and the roof of the structure, wherein the structure is a habitable structure.

23. The method of claim 22, further comprising:
positioning the second end of the tubular structure to transmit sunlight from the interior of the tubular structure to a room in the habitable structure.
